(19) United States
(12) Patent Application Publication
(10) Pub. No.: US 2010/0195687 A1
(43) Pub. Date: Aug. 5, 2010

(54) Semiconductor laser device

(75) Inventors: Kuniyoshi Okamoto, Kyoto (JP); Masashi Kubota, Kyoto (JP); Taketoshi Tanaka, Kyoto (JP); Junichi Kashiwagi, Kyoto (JP); Yoshinori Tanaka, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/656,493

(22) Filed: Feb. 1, 2010

(30) Foreign Application Priority Data
Feb. 2, 2009 (JP) 2009-021952

(51) Int. Cl. H01S 5/34; H01S 5/323

(52) U.S. Cl. 372/45.012; 372/45.01

(57) ABSTRACT

A semiconductor laser device has a semiconductor laser diode structure made of group III nitride semiconductors having major growth surfaces defined by nonpolar planes or semipolar planes. The semiconductor laser diode structure includes a p-type cladding layer and an n-type cladding layer, a p-type guide layer and an n-type guide layer held between the p-type cladding layer and the n-type cladding layer, and an active layer containing In held between the p-type guide layer and the n-type guide layer. The In compositions in the p-type guide layer and the n-type guide layer are increased as approaching the active layer respectively. Each of the p-type guide layer and the n-type guide layer may have a plurality of InₓGa₁₋ₓN layers (0≦x≦1). In this case, the plurality of InₓGa₁₋ₓN layers may be stacked in such order that the In compositions therein are increased as approaching the active layer.

### BACKGROUND OF THE INVENTION

1. Field of the Invention

The present invention relates to a semiconductor laser device having a semiconductor laser diode structure made of group III nitride semiconductors.

2. Description of Related Art

Group III nitride semiconductors are group III-V semiconductors employing nitrogen as a group V element, and typical examples thereof include aluminum nitride (AlN), gallium nitride (GaN) and indium nitride (InN). The group III nitride semiconductors can be generally expressed as Al_{X}In_{Y}Ga_{1-X-Y}N (0≦X≦1, 0≦Y≦1 and 0≦X+Y≦1).

A violet short-wavelength laser source is increasingly used in the fields of high-density recording in an optical disk represented by a DVD, image processing, medical equipment, measuring equipment and the like. Such a short-wavelength laser source is constituted of a laser diode employing GaN semiconductors, for example.

A GaN semiconductor laser diode is manufactured by growing group III nitride semiconductors on a gallium nitride (GaN) substrate having a major surface defined by a c-plane by metal-organic vapor phase epitaxy (MOVPE). More specifically, an n-type GaN contact layer, an n-type AlGaN cladding layer, an n-type GaN guide layer, an active layer (a light emitting layer), a p-type GaN guide layer, a p-type AlGaN cladding layer and a p-type GaN contact layer are successively grown on the GaN substrate by metal-organic vapor phase epitaxy, to form a semiconductor multilayer structure consisting of the semiconductor layers. The active layer emits light by recombination of electrons injected from the n-type layers and holes injected from the p-type layers. The light is confined between the n-type AlGaN cladding layer and the p-type AlGaN cladding layer, and propagated in a direction perpendicular to the stacking direction of the semiconductor multilayer structure. Cavity end faces are formed on both ends in the propagation direction, and the light is resonantly amplified between the pair of cavity end faces while repeating induced emission, and partially emitted from the cavity end faces as laser beams.

### SUMMARY OF THE INVENTION

One of the important characteristics of a semiconductor laser diode is a threshold current (an oscillation threshold) for causing laser oscillation. Laser oscillation having superior energy efficiency is enabled as the threshold current is reduced.

However, light emitted from an active layer grown on a major surface defined by a c-plane is randomly polarized, and hence the ratio of light contributing to oscillation of a TE mode is small. Therefore, the efficiency of the laser oscillation is not necessarily excellent, and the semiconductor laser diode can be still improved in order to reduce the threshold current.

A laser diode having a major surface defined by a nonpolar plane such as an m-plane is proposed. When a laser diode is manufactured in a group III nitride semiconductor structure having major crystal growth surfaces defined by m-planes, for example, an active layer emits light containing a large amount of polarization components parallel to the m-planes (more specifically, polarization components in an a-axis direction). Thus, the light emitted in the active layer can contribute to laser oscillation in a high ratio, whereby the efficiency of the laser oscillation is improved, and the threshold current can be reduced.

When the active layer has a quantum well structure (more specifically, a quantum well structure containing In), separation of carriers resulting from spontaneous piezoelectric polarization in quantum wells is suppressed, whereby luminous efficiency is improved also by this. Further, the major surfaces of crystal growth are so defined by m-planes that the crystal growth can be extremely stably performed, and crystallinity can be improved as compared with a case of defining major surfaces of crystal growth by c-planes or other crystal planes. Consequently, a high-performance laser diode can be manufactured.

In order to set an emission wavelength in a long wave range of not less than 450 nm, on the other hand, In compositions in quantum well layers must be increased. In order to ensure a refractive index difference for light confinement, further, InGaN layers must be applied to guide layers.

If InGaN quantum well layers and InGaN guide layers are coherently grown on an m-plane GaN layer, however, in-plane anisotropic compressive stress acts on the layers. More specifically, relatively large compressive stress is caused along a direction perpendicular to c-axes, i.e., along an a-axis direction. This is because the a-axis lattice constant of InGaN is larger than that of GaN. If the In compositions in or the thicknesses of the InGaN quantum well layers or the InGaN guide layers are increased, therefore, crystal defects are caused along a-planes. When observed with a fluorescent microscope, the crystal defects are recognized as dark lines parallel to the a-planes. Therefore, the crystal defects are conceivably non-luminous defects. If such non-luminous defects can be suppressed, the luminous efficiency can conceivably be further improved.

In order to ensure the refractive index difference for light confinement, the Al compositions in AlGaN cladding layers may be increased. In this case, however, crystals are cracked, and an operable semiconductor laser cannot be manufactured due to current leakage resulting from such cracking.

Similar problems arise also in a laser device employing group III nitride semiconductors having major growth surfaces defined by a-planes which are other nonpolar planes or semipolar planes.

An object of the present invention is to provide a semiconductor laser device having a low threshold current and high luminous efficiency with group III nitride semiconductors having major growth surfaces defined by nonpolar planes or semipolar planes.

The foregoing and other objects, features and effects of the present invention will become more apparent from the following detailed description of the embodiments with reference to the attached drawings.

### BRIEF DESCRIPTION OF THE DRAWINGS

FIG. 1 is a perspective view for illustrating the structure of a semiconductor laser diode according to an embodiment of the present invention.

FIG. 2 is a longitudinal sectional view taken along a line II-II in FIG. 1.

FIG. 3 is a cross sectional view taken along a line in FIG. 1.

FIG. 4 is a schematic sectional view for illustrating the structure of an active layer of the semiconductor laser diode.

FIG. 5 is a schematic diagram for illustrating the structures of insulating films (reflection films) formed on cavity end faces.

FIG. 6 is a schematic diagram showing a unit cell of the crystal structure of a group III nitride semiconductor.

FIG. 7 is a diagram showing examples of compositions of layers constituting a group III nitride semiconductor multilayer structure.

FIG. 8 is a diagram showing other examples of the compositions of the layers constituting the group III nitride semiconductor multilayer structure.

FIG. 9A is a diagram schematically showing the refractive indices of the layers in the structure shown in FIG. 7, and FIG. 9B is a diagram schematically showing the refractive indices of the layers in the structure shown in FIG. 8.

FIG. 10 is a diagram showing further examples of compositions of the layers constituting the group III nitride semiconductor multilayer structure.

FIGS. 11A to 11H are diagrams showing results of a simulation of optical intensity conducted on the structure shown in FIG. 7.

FIGS. 12A to 12H are diagrams showing results of another simulation of optical intensity conducted on the structure shown in FIG. 7.

FIGS. 13A to 13G are diagrams showing results of still another simulation of optical intensity conducted on the structure shown in FIG. 7.

FIG. 14 is a schematic diagram for illustrating the structure of a processing apparatus for growing respective layers constituting a group III nitride semiconductor multilayer structure.

### DETAILED DESCRIPTION OF PREFERRED EMBODIMENTS

An embodiment of the present invention provides a semiconductor laser device having a semiconductor laser diode structure made of group III nitride semiconductors having major growth surfaces defined by nonpolar planes or semipolar planes. The semiconductor laser diode structure includes a p-type cladding layer and an n-type cladding layer, a p-type guide layer and an n-type guide layer held between the p-type cladding layer and the n-type cladding layer, and an active layer containing In held between the p-type guide layer and the n-type guide layer. The In compositions in the p-type guide layer and the n-type guide layer are increased as approaching the active layer respectively.

According to the structure, the In compositions in the guide layers are increased as approaching the active layer (a light emitting layer), whereby an excellent light confining effect can be attained. In other words, the thicknesses of the guide layers may not be increased, or the total In composition therein may not be increased. When the cladding layers are made of AlGaN, for example, the Al compositions therein may not be excessively increased either. On the other hand, the In compositions are reduced as separating from the active layer, whereby lattice mismatching is relaxed when the laser diode structure made of the group III nitride semiconductors is formed on a GaN layer, for example. Therefore, defects resulting from lattice mismatching can be suppressed, whereby the laser diode structure can have excellent crystallinity. Thus, a semiconductor laser device capable of attaining excellent luminous efficiency can be implemented while implementing a low threshold current with the group III nitride semiconductors having the major surfaces defined by the nonpolar planes or the semipolar planes.

While the In compositions in the guide layers may be continuously reduced as approaching the active layer. Alternatively, each of the p-type guide layer and the n-type guide layer may have a plurality of InₓGa₁₋ₓN layers (0≦x≦1), and the plurality of InₓGa₁₋ₓN layers may be stacked in such order that the In compositions therein are increased as approaching the active layer. In this case, the In compositions in the InₓGa₁₋ₓN layers are increased stepwise as approaching the active layer.

In the aforementioned structure, at least one of the plurality of InₓGa₁₋ₓN layers may be constituted of an InGaN superlattice, and an average In composition may be modulated by adjusting the ratio between the thicknesses of layers constituting the InGaN superlattice. More specifically, the plurality of InₓGa₁₋ₓN layers constituting each guide layer can be constituted of a superlattice obtained by repetitively stacking first Inₓ₁Ga₁₋ₓ₁N layers each having a large In composition and second Inₓ₂Ga₁₋ₓ₂N layers (0≦x2≦x1≦1) each having a small In composition. In this case, an average InGaN composition in the overall superlattice can be modulated by changing the ratio between the thicknesses of the first Inₓ₁Ga₁₋ₓ₁N layers and the second Inₓ₂Ga₁₋ₓ₂N layers.

In the aforementioned structure, a p-type AlGaN electron blocking layer may be interposed in an intermediate portion of the total thickness of the p-type guide layer.

The p-type AlGaN electron blocking layer prevents an overflow of carriers. The p-type AlGaN electron blocking layer having a small refractive index may weaken light confinement if the same is positioned in the vicinity of the active layer. According to the present invention, therefore, the p-type AlGaN electron blocking layer is interposed in the intermediate portion of the total thickness of the p-type guide layer. Thus, the p-type AlGaN electron blocking layer can be arranged on a position separating from the active layer, whereby light confinement can be reinforced. Thus, the luminous efficiency can be further improved.

In the aforementioned structure, the distance from the active layer to the p-type AlGaN electron blocking layer may be not less than 40 nm.

The p-type AlGaN electron blocking layer is arranged at the distance of not less than 40 nm from the active layer, whereby a sufficient light confining effect can be attained, and an influence exerted by the p-type AlGaN electron blocking layer on the profile of optical intensity can be sufficiently suppressed. Thus, a semiconductor laser device having high luminous efficiency can be implemented.

In the aforementioned structure, the distance from the active layer to the p-type AlGaN electron blocking layer may be not less than 40 nm and not more than 100 nm.

The p-type AlGaN electron blocking layer is arranged in the range of the distance of 40 nm to 100 nm from the active layer, whereby sufficiently high optical intensity can be obtained in addition to the aforementioned effect. In other words, a carrier confining effect can be sufficiently attained due to the action of the p-type AlGaN electron blocking layer, whereby the profile of the optical intensity has a sufficiently steep shape. Thus, light confinement and carrier confinement can be excellently performed, to contribute to improvement of the luminous efficiency.

The embodiment of the present invention is now described in further detail with reference to the attached drawings.

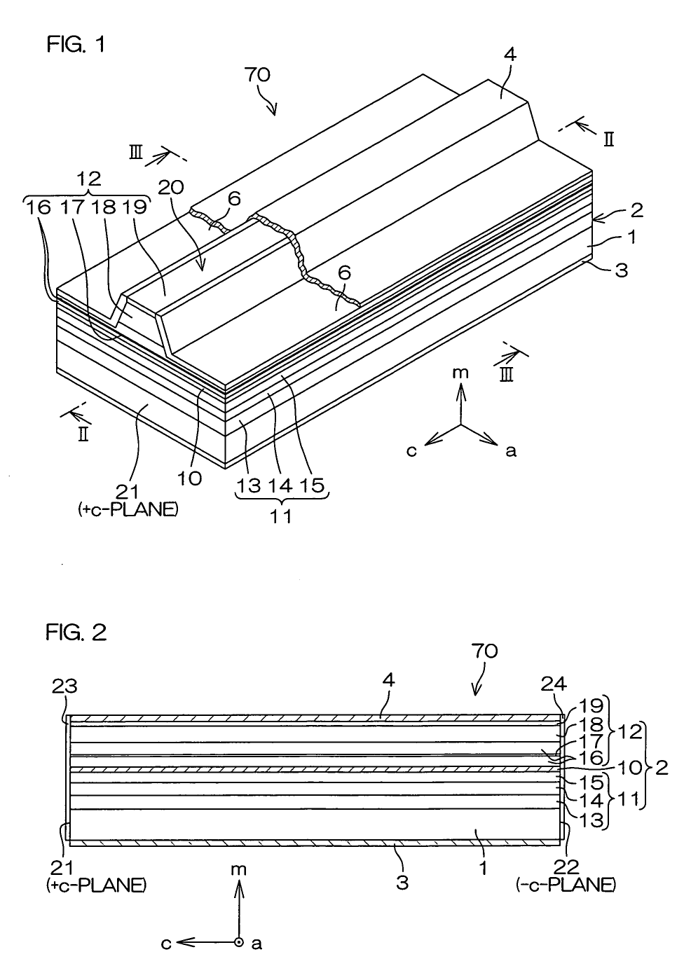

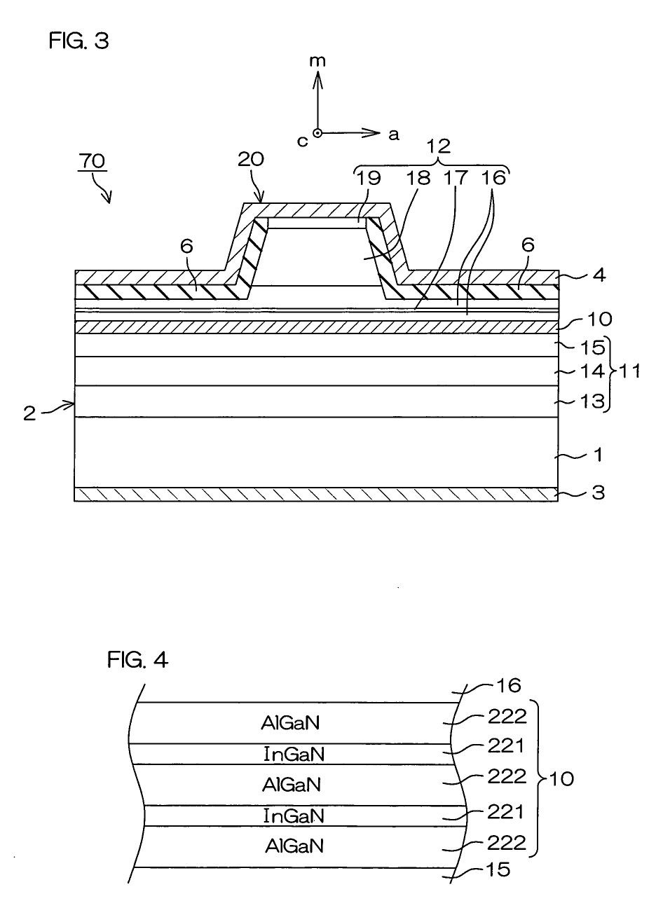

FIG. 1 is a perspective view for illustrating the structure of a semiconductor laser diode according to the embodiment of the present invention, FIG. 2 is a longitudinal sectional view taken along a line II-II in FIG. 1, and FIG. 3 is a cross sectional view taken along a line in FIG. 1.

A semiconductor laser diode 70 is a Fabry-Perot laser diode including a substrate 1, a group III nitride semiconductor multilayer structure 2 formed on the substrate 1 by crystal growth, an n-type electrode 3 formed to be in contact with the rear surface (the surface opposite to the group III nitride semiconductor multilayer structure 2) of the substrate 1 and a p-type electrode 4 formed to be in contact with the surface of the group III nitride semiconductor multilayer structure 2.

The substrate 1 is constituted of a GaN single-crystalline substrate in this embodiment. The substrate 1 has a major surface defined by an m-plane which is one of nonpolar planes, and the group III nitride semiconductor multilayer structure 2 is formed by crystal growth on the major surface. Therefore, the group III nitride semiconductor multilayer structure 2 is made of group III nitride semiconductors having major crystal growth surfaces defined by m-planes.

The layers forming the group III nitride semiconductor multilayer structure 2 are coherently grown with respect to the substrate 1. Coherent growth denotes crystal growth in a state keeping continuity of a lattice from an underlayer. Lattice mismatching with the underlayer is absorbed by strain of the lattice of the crystal-grown layer, and continuity of the lattice on the interface between the same and the underlayer is maintained. An a-axis lattice constant of InGaN in an unstrained state is greater than that of GaN, and hence compressive stress (compressive strain) in an a-axis direction is applied to an InGaN layer.

The group III nitride semiconductor multilayer structure 2 includes an active layer (a light emitting layer) 10, an n-type semiconductor layered portion 11 and a p-type semiconductor layered portion 12. The n-type semiconductor layered portion 11 is disposed on a side of the active layer 10 closer to the substrate 1, while the p-type semiconductor layered portion 12 is disposed on a side of the active layer 10 closer to the p-type electrode 4. Thus, the active layer 10 is held between the n-type semiconductor layered portion 11 and the p-type semiconductor layered portion 12, whereby a double heterojunction is provided. Electrons and holes are injected into the active layer 10 from the n-type semiconductor layered portion 11 and the p-type semiconductor layered portion 12 respectively. The electrons and the holes are recombined in the active layer 10, to emit light.

The n-type semiconductor layered portion 11 is formed by successively stacking an n-type GaN contact layer 13 (having a thickness of 2 μm, for example), an n-type AlGaN cladding layer 14 (having a thickness of not more than 1.5 μm such as a thickness of 1.0 μm, for example) and an n-type guide layer 15 (having a total thickness of 0.1 μm, for example) from the side closer to the substrate 1. On the other hand, the p-type semiconductor layered portion 12 is formed by successively stacking a p-type guide layer 16 (having a total thickness of 0.1 μm, for example), a p-type AlGaN electron blocking layer 17 (having a thickness of 20 nm, for example), a p-type AlGaN cladding layer 18 (having a thickness of not more than 1.5 μm such as a thickness of 0.4 μm, for example) and a p-type GaN contact layer 19 (having a thickness of 0.3 μm, for example) on the active layer 10. The p-type AlGaN electron blocking layer 17 is interposed in an intermediate portion of the total thickness of the p-type guide layer 16. In other words, the p-type guide layer 16 is divided into an inner portion closer to the active layer 10 and an outer portion closer to the p-type AlGaN cladding layer 18 with the p-type AlGaN electron blocking layer 17 interposed therebetween.

The n-type GaN contact layer 13 is a low-resistance layer. The p-type GaN contact layer 19 is a low-resistance layer for attaining ohmic contact with the p-type electrode 4. The n-type GaN contact layer 13 is made of an n-type semiconductor prepared by doping GaN with Si, for example, serving as an n-type dopant in a high doping concentration (3×10¹⁸ cm⁻³, for example). The p-type GaN contact layer 19 is made of a p-type semiconductor prepared by doping GaN with Mg serving as a p-type dopant in a high doping concentration (3×10¹⁹ cm⁻³, for example).

The n-type AlGaN cladding layer 14 and the p-type AlGaN cladding layer 18 provide a light confining effect confining light emitted by the active layer 10 therebetween. The n-type AlGaN cladding layer 14 is made of an n-type semiconductor prepared by doping AlGaN with Si, for example, serving as an n-type dopant (in a doping concentration of 1×10¹⁸ cm⁻³, for example). The p-type AlGaN cladding layer 18 is made of a p-type semiconductor prepared by doping AlGaN with Mg serving as a p-type dopant (in a doping concentration of 1×10¹⁹ cm⁻³, for example). The band gap of the n-type AlGaN cladding layer 14 is wider than that of the n-type guide layer 15, and the band gap of the p-type AlGaN cladding layer 18 is wider than that of the p-type guide layer 16. Thus, the light can be excellently confined, and a semiconductor laser diode having high efficiency can be implemented.

When the emission wavelength of the active layer 10 is set in a long wave range of not less than 450 nm, the n-type AlGaN cladding layer 14 and the p-type AlGaN cladding layer 18 are preferably constituted of AlGaN having an average Al composition of not more than 5%. Thus, cracking can be suppressed. The cladding layers 14 and 18 can also be constituted of superlattice structures of AlGaN layers and GaN layers. Also in this case, the average Al composition in the overall cladding layers 14 and 18 is preferably set to not more than 5%.

The n-type guide layer 15 and the p-type guide layer 16 are semiconductor layers providing a carrier confining effect for confining carriers (electrons and holes) in the active layer 10, and form a light confining structure in the active layer 10 along with the cladding layers 14 and 18. Thus, the efficiency of recombination of the electrons and the holes in the active layer 10 is improved. The n-type guide layer 15 is made of an n-type semiconductor prepared by doping the material therefor with Si, for example, serving as an n-type dopant (in a doping concentration of 1×10¹⁸ cm⁻³, for example), while the p-type guide layer 16 is made of a p-type semiconductor prepared by doping the material therefor with Mg, for example, serving as a p-type dopant (in a doping concentration of 5×10¹⁸ cm⁻³, for example).

The p-type AlGaN electron blocking layer 17 is made of a p-type semiconductor prepared by doping AlGaN with Mg, for example, serving as a p-type dopant (in a doping concentration of 5×10¹⁸ cm⁻³, for example), and improves the efficiency of recombination of the electrons and the holes by preventing the electrons from flowing out of the active layer 10.

The active layer 10, having an MQW (multiple-quantum well) structure containing InGaN, for example, is a layer for emitting light by recombination of the electrons and the holes and amplifying the emitted light.

According to the embodiment, the active layer 10 has a multiple-quantum well (MQW) structure formed by alternately repetitively stacking quantum well layers (each having a thickness of 3 nm, for example) 221 consisting of InGaN layers and barrier layers 222 consisting of AlGaN layers by a plurality of cycles, as shown in FIG. 4. In this case, the In composition ratio in each quantum well layer 221 made of InGaN is set to not less than 5%, whereby the quantum well layer 221 has a relatively small band gap while each barrier layer 222 made of AlGaN has a relatively large band gap. The quantum well layers 221 and the barrier layers 222 are alternately repetitively stacked by two to seven cycles, for example, to constitute the active layer 10 having the multiple-quantum well structure. The emission wavelength corresponds to the band gap of the quantum well layers 221, and the band gap can be adjusted by adjusting the composition ratio of indium (In). The band gap is reduced and the emission wavelength is increased as the composition ratio of indium is increased. According to the present embodiment, the emission wavelength is set to 450 nm to 550 nm by adjusting the composition of In in the quantum well layers (InGaN layers) 221. In the multiple-quantum well structure, the number of the quantum well layers 221 containing In is preferably set to not more than three.

The thickness of each barrier layer 222 is set to 3 nm to 8 nm (7 nm, for example). Thus, the average refractive index around the active layer 10 can be increased, whereby an excellent light confining effect is attained and a low threshold current can be implemented. For example, a threshold current of not more than 100 mA considered as a criterion for continuous-wave oscillation can be implemented. The function of the barrier layer 222 is hard to obtain if the thickness of the barrier layer 222 is less than 3 nm, while the light confining effect around the active layer 10 may be weakened to cause difficulty in continuous-wave oscillation if the thickness of the barrier layer 222 exceeds 8 nm.

In order to further increase the average refractive index around the active layer 10 for more strongly confining the light, the Al composition in each barrier layer 222 is preferably set to not more than 5%.

As shown in FIG. 1 etc., the p-type semiconductor layered portion 12 is partially removed, to form a ridge stripe 20. More specifically, the p-type contact layer 19, the p-type AlGaN cladding layer 18 and the p-type guide layer 16 are partially removed by etching, to form the ridge stripe 20 having a generally trapezoidal shape (a mesa shape) in cross sectional view. The ridge stripe 20 is formed along the c-axis direction.

The group III nitride semiconductor multilayer structure 2 has a pair of end faces 21 and 22 (cleavage planes) formed by cleaving both ends of the ridge stripe 20 in the longitudinal direction. The pair of end faces 21 and 22 are parallel to each other, and perpendicular to c-axes. Thus, the n-type guide layer 15, the active layer 10 and the p-type guide layer 17 form a Fabry-Perot cavity with the end faces 21 and 22 serving as cavity end faces. In other words, the light emitted in the active layer 10 reciprocates between the cavity end faces 21 and 22, and is amplified by induced emission. The amplified light is partially extracted from the cavity end faces 21 and 22 as laser beams.

The n-type electrode 3 and the p-type electrode 4, made of an Al metal, for example, are in ohmic contact with the p-type contact layer 19 and the substrate 1 respectively. Insulating layers 6 covering exposed surfaces of the p-type guide layer 16 and the p-type AlGaN cladding layer 18 are so provided that the p-type electrode 4 is in contact with only the p-type GaN contact layer 19 provided on the top face (a striped contact region) of the ridge stripe 20. Thus, a current can be concentrated on the ridge stripe 20, thereby enabling efficient laser oscillation. Regions of the surface of the ridge stripe 20 excluding the portion in contact with the p-type electrode 4 are covered with the insulating layers 6, whereby control can be simplified by moderating lateral light confinement and leakage currents from the side surfaces can be prevented. The insulating layers 6 can be made of an insulating material such as SiO₂ or ZrO₂, for example, having a refractive index greater than 1.

The top face of the ridge stripe 20 is defined by an m-plane, and the p-type electrode 4 is formed on them-plane. The rear surface of the substrate 1 provided with the n-type electrode 3 is also defined by an m-plane. Thus, both of the p-type electrode 4 and the n-type electrode 3 are formed on them-planes, whereby reliability for sufficiently withstanding increase in the laser output and a high-temperature operation can be implemented.

The cavity end faces 21 and 22 are covered with insulating films 23 and 24 (not shown in FIG. 1) respectively. The cavity end face 21 is a +c-axis-side end face, and the cavity end face 22 is −c-axis-side end face. In other words, the crystal plane of the cavity end face 21 is a +c-plane, and that of the cavity end face 22 is −c-plane. The insulating film 24 provided on the −c-plane-side can function as a protective film protecting the chemically weak-c-plane dissolved in alkali, and contributes to improvement in the reliability of the semiconductor laser diode 70.

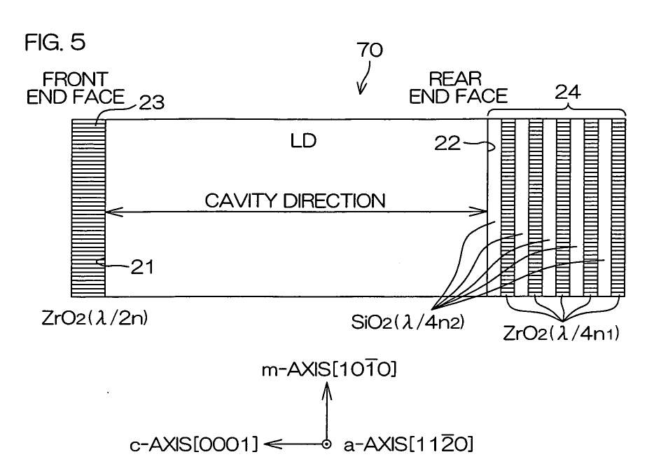

As schematically shown in FIG. 5, the insulating film 23 formed to cover the cavity end face 21 defined by the +c-plane consists of a single film of ZrO₂, for example. On the other hand, the insulating film 24 formed on the cavity end face 22 defined by the −c-plane is constituted of a multiple reflection film formed by alternately repetitively stacking SiO₂ films and ZrO₂ films a plurality of times (five times in the example shown in FIG. 5), for example. The thickness of the single film of ZrO₂ constituting the insulating film 23 is set to λ/2n₁ (where λ represents the emission wavelength of the active layer 10, and n₁ represents the refractive index of ZrO₂). On the other hand, the multiple reflection film constituting the insulating film 24 is formed by alternately stacking SiO₂ films each having a thickness of λ/4n₂ (where n₂ represents the refractive index of SiO₂) and ZrO₂ films each having a thickness of λ/4n₁.

According to such a structure, the reflectance on the +c-axis-side end face 21 is small, and that on the −c-axis-side end face 22 is large. More specifically, the reflectance on the +c-axis-side end face 21 is about 20%, and the reflectance on the −c-axis-side end face 22 is about 99.5% (generally 100%), for example. Therefore, the +c-axis-side end face 21 outputs a larger laser output. In other words, the +c-axis-side end face 21 serves as a laser emitting end face in the semiconductor laser diode 70.

According to the structure, light having a wavelength of 450 nm to 550 nm can be emitted by connecting the n-type electrode 3 and the p-type electrode 4 to a power source and injecting the electrons and the holes into the active layer 10 from the n-type semiconductor layered portion 11 and the p-type semiconductor layered portion 12 respectively thereby recombining the electrons and the holes in the active layer 10. The light reciprocates between the cavity end faces 21 and 22 along the guide layers 15 and 17, and is amplified by induced emission. Then, a larger quantity of laser output is extracted from the cavity end face 21 serving as the laser emitting end face.

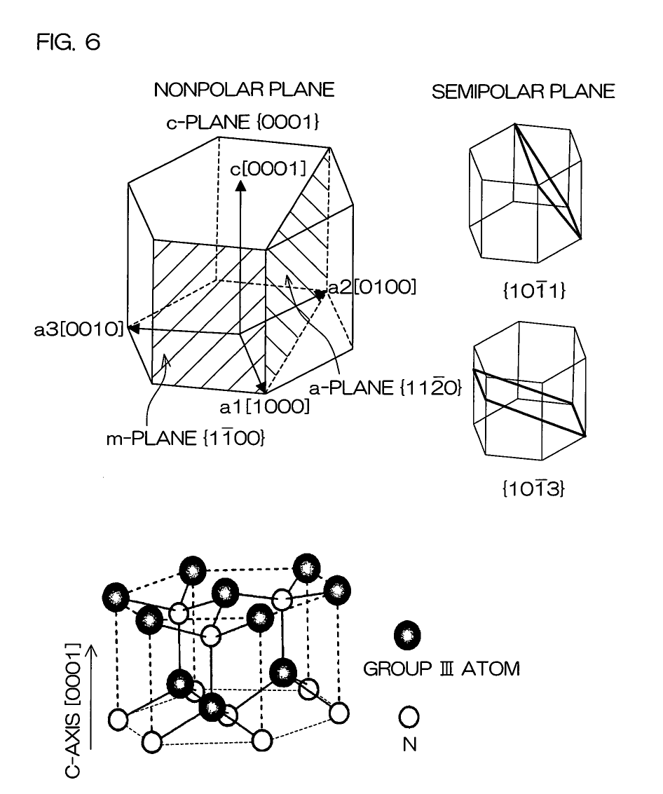

FIG. 6 is a schematic diagram showing a unit cell of the crystal structure of a group III nitride semiconductor. The crystal structure of the group III nitride semiconductor can be approximated by a hexagonal system, and four nitrogen atoms are bonded to each group III atom. The four nitrogen atoms are located on four vertices of a regular tetrahedron having the group III atom disposed at the center thereof. One of the four nitrogen atoms is located in a +c-axis direction of the group III atom, while the remaining three nitrogen atoms are located on −c-axis side of the group III atom. Due to the structure, the direction of polarization of the group III nitride semiconductor is along the c-axis.

The c-axis is along the axial direction of a hexagonal prism, and a surface (the top face of the hexagonal prism) having the c-axis as a normal is a c-plane (0001). When a crystal of the group III nitride semiconductor is cleaved along two planes parallel to the c-plane, group III atoms align on the crystal plane (+c-plane) on the +c-axis side, and nitrogen atoms align on the crystal plane (−c-plane) on the −c-axis side. Therefore, the c-planes, exhibiting different properties on the +c-axis side and the −c-axis side, are called polar planes.

The +c-plane and the −c-plane are different crystal planes, and hence responsively exhibit different physical properties. More specifically, it has been recognized that the +c-plane has high durability against chemical reactivity such as high resistance against alkali, while the −c-plane is chemically weak and dissolved in alkali, for example.

On the other hand, the side surfaces of the hexagonal prism are defined by m-planes (10-10) respectively, and a surface passing through a pair of unadjacent ridges is defined by an a-plane (11-20). The planes, perpendicular to the c-planes and orthogonal to the direction of polarization, are planes having no polarity, i.e., nonpolar planes. Crystal planes inclined (neither parallel nor perpendicular) with respect to the c-planes, obliquely intersecting with the direction of polarization, are planes having slight polarity, i.e., semipolar planes. Specific examples of the semipolar planes are a (10-1-1) plane, a (10-1-3) plane, a (11-22) plane and the like.

T. Takeuchi et al., Jap. J. Appl. Phys. 39, 413-416, 2000 describes the relation between angles of deviation of crystal planes with respect to c-planes and polarization of the crystal planes in normal directions. From the document, it can be said that a (11-24) plane, a (10-12) plane etc. are also less polarized and powerful candidates for crystal planes employable for extracting largely polarized light.

For example, a GaN single-crystalline substrate having a major surface defined by an m-plane can be cut out of a GaN single crystal having a major surface defined by a c-plane. The m-plane of the cut substrate is polished by chemical mechanical polishing, for example, so that azimuth errors with respect to both of a (0001) direction and a (11-20) direction are within ±1° (preferably within ±0.3°). Thus, a GaN single-crystalline substrate having a major surface defined by an m-plane is obtained with no crystal defects such as dislocations and stacking faults. Only steps of an atomic level are formed on the surface of the GaN single-crystalline substrate.

The group III nitride semiconductor multilayer structure 2 constituting a semiconductor laser diode structure is grown on the GaN single-crystalline substrate obtained in the aforementioned manner by metal-organic chemical vapor deposition.

When the group III nitride semiconductor multilayer structure 2 having the major growth surface defined by an m-plane is grown on the GaN single-crystalline substrate 1 having the major surface defined by an m-plane and a section along an a-plane is observed with an electron microscope (STEM: scanning transmission electron microscope), no striations showing the presence of dislocations are observed in the group III nitride semiconductor multilayer structure 2. When the surface state is observed with an optical microscope, it is understood that planarity in a c-axis direction (the difference between the heights of a terminal portion and a lowermost portion) is not more than 10 Å. This means that planarity of the active layer 10, particularly the quantum well layers, in the c-axis direction is not more than 10 Å, and the half band width of an emission spectrum can be reduced.

Thus, dislocation-free m-plane group III nitride semiconductors having planar stacking interfaces can be grown. However, the offset angle of the major surface of the GaN single-crystalline substrate 1 is preferably set within ±1° (preferably within ±0.3°). If GaN semiconductor layers are grown on an m-plane GaN single-crystalline substrate having an offset angle set to 2°, for example, GaN crystals may be grown in the form of terraces and a planar surface state may not be obtained dissimilarly to the case of setting the offset angle within ±1°.

Group III nitride semiconductors crystal-gown on the GaN single-crystalline substrate having the major surface defined by an m-plane are grown with major growth surfaces defined by m-planes. If the group III nitride semiconductors are crystal-grown with major surfaces defined by c-planes, luminous efficiency in the active layer 10 may be deteriorated due to an influence by polarization in the c-axis direction. When the major growth surfaces are defined by m-planes, on the other hand, polarization in the quantum well layers is suppressed, and the luminous efficiency is increased. Thus, reduction of a threshold and increase in slope efficiency can be implemented. Current dependency of the emission wavelength is suppressed due to small polarization, and a stable oscillation wavelength can be implemented.

Further, anisotropy in physical properties is caused in the c-axis direction and the a-axis direction due to the major surfaces defined by m-planes. In addition, biaxial stress resulting from lattice strain is caused in the active layer 10 containing In. Consequently, a quantum band structure is different from that of an active layer crystal-grown with major surfaces defined by c-planes. Therefore, a gain different from that of the active layer having the major growth surfaces defined by c-planes is obtained, and laser characteristics are improved.

The major surfaces of crystal growth are so defined by m-planes that group III nitride semiconductor crystals can be extremely stably grown, and crystallinity can be further improved as compared with a case of defining the major crystal growth surfaces by c-planes or a-planes. Thus, a high-performance laser diode can be prepared.

The active layer 10 is formed by group III nitride semiconductors grown with major crystal growth surfaces defined by m-planes, and hence the light emitted from the active layer 10 is polarized in an a-axis direction, i.e., a direction parallel to them-planes, and travels in a c-axis direction in the case of a TE mode. Therefore, the major crystal growth surface of the semiconductor laser diode 70 is parallel to the direction of polarization, and a stripe direction, i.e., the direction of a waveguide is set parallel to the traveling direction of the light. Thus, oscillation of the TE mode can be easily caused, and a threshold current for causing laser oscillation can be reduced.

According to the embodiment, a GaN single-crystalline substrate is employed as the substrate 1, whereby the group III nitride semiconductor multilayer structure 2 can have high crystal quality with a small number of defects. Consequently, a high-performance laser diode can be implemented.

Further, the group III nitride semiconductor multilayer structure 2 grown on the GaN single-crystalline substrate having generally no dislocations can be formed by excellent crystals having neither stacking faults nor threading dislocations from a regrowth surface (m-plane) of the substrate 1. Thus, characteristic deterioration such as reduction in luminous efficiency resulting from defects can be suppressed.

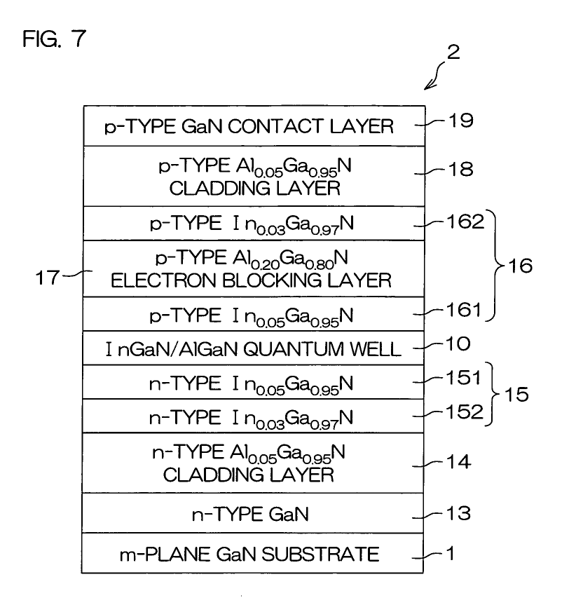

FIG. 7 is a diagram showing examples of compositions of the layers constituting the group III nitride semiconductor multilayer structure 2. Referring to FIG. 7, the n-type guide layer 15 is formed by stacking a first portion 151 made of InGaN (In_{0.05}Ga_{0.95}N in the example shown in FIG. 7) having a relatively large In composition and a second portion 152 made of InGaN (In_{0.03}Ga_{0.97}N in the example shown in FIG. 7) having a relatively small In composition. The first portion 151 having the relatively large In composition is disposed on a side closer to the active layer 10 than the second portion 152 having the relatively small In composition.

Similarly, the p-type guide layer 16 includes a first portion 161 made of InGaN (In_{0.05}Ga_{0.95}N in the example shown in FIG. 7) having a relatively large In composition and a second portion 162 made of InGaN (In_{0.03}Ga_{0.97}N in the example shown in FIG. 7) having a relatively small In composition, and the p-type AlGaN electron blocking layer 17 is interposed therebetween. The first portion 161 having the relatively large In composition is disposed on a side closer to the active layer 10 than the second portion 162 having the relatively small In composition. In other words, the first portion 161, the p-type AlGaN electron blocking layer 17 and the second portion 162 are stacked in this order successively from the side closer to the active layer 10.

The p-type AlGaN electron blocking layer 17 is made of Al_{0.2}Ga_{0.8}N in the example shown in FIG. 7. Each of the n-type cladding layer 15 and the p-type cladding layer 18 is made of Al_{0.05}Ga_{0.95}N in the example shown in FIG. 7.

The p-type electron blocking layer 17 may not be arranged between the first portion 161 and the second portion 162 having different In compositions, but may alternatively be arranged in an intermediate portion of the thickness of the first portion 161 or the second portion 162. In other words, guide layer portions in contact with first and second sides of the p-type electron blocking layer 17 respectively may have different or equal compositions. If the distance from the active layer 10 to the p-type electron blocking layer 17 is excessively increased, however, a function of suppressing an overflow of carriers may be reduced, to result in inferior luminous efficiency.

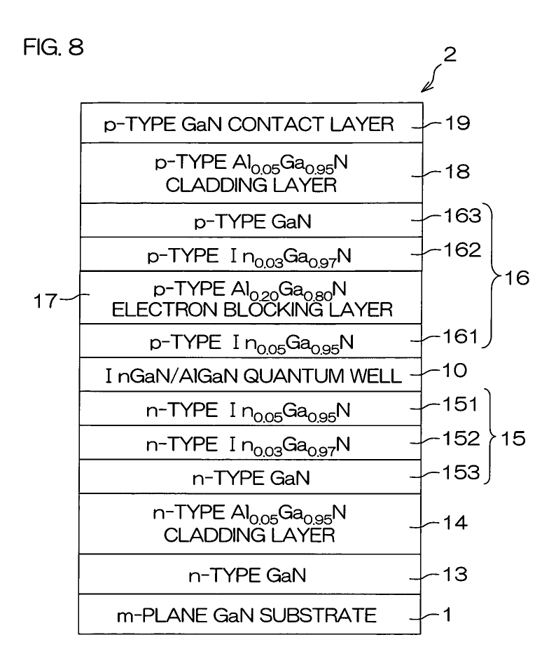

FIG. 8 is a diagram showing other examples of the compositions of the layers constituting the group III nitride semiconductor multilayer structure 2. Referring to FIG. 8, the n-type guide layer 15 is formed by stacking a first portion 151, a second portion 152 and a third portion 153. The first portion 151 is made of InGaN (In_{0.05}Ga_{0.95}N in the example shown in FIG. 8) having the largest In composition, the second portion 152 is made of InGaN (In_{0.03}Ga_{0.97}N in the example shown in FIG. 8) having the second largest In composition, and the third portion 153 is made of InGaN (GaN in the example shown in FIG. 8, i.e., the third portion 153 contains no In) having the smallest In composition. The first portion 151 having the largest In composition is disposed on a side closer to the active layer 10 than the second and third portions 152 and 153. The second portion 152 having the second largest In composition is disposed on a side closer to the active layer 10 than the third portion 153 containing no In.

Similarly, the p-type guide layer 16 has a first portion 161, a second portion 162 and a third portion 163. The first portion 161 is made of InGaN (In_{0.05}Ga_{0.95}N in the example shown in FIG. 8) having the largest In composition, the second portion 162 is made of InGaN (In_{0.03}Ga_{0.97}N in the example shown in FIG. 8) having the second largest In composition, and the third portion 163 is made of InGaN (GaN in the example shown in FIG. 8, i.e., the third portion 163 contains no In) having the smallest In composition. The p-type AlGaN electron blocking layer 17 is interposed between the first and second portions 161 and 162. The first portion 161 having the largest In composition is disposed on a side closer to the active layer 10 than the second and third portions 162 and 163. The second portion 162 having the second largest In composition is disposed on a side closer to the active layer 10 than the third portion 163 containing no In. In other words, the first portion 161, the p-type AlGaN electron blocking layer 17, the second portion 162 and the third portion 163 are stacked in this order successively from the side closer to the active layer 10.

The p-type AlGaN electron blocking layer 17 is made of Al_{0.2}Ga_{0.8}N in the example shown in FIG. 8. Each of the n-type cladding layer 15 and the p-type cladding layer 18 is made of Al_{0.05}Ga_{0.95}N in the example shown in FIG. 8.

The p-type electron blocking layer 17 may not be arranged between the first portion 161 and the second portion 162 having different In compositions, but may alternatively be arranged in an intermediate portion of the thickness of the first portion 161, the second portion 162 or the third portion 163. Further alternatively, the p-type electron blocking layer 17 may be arranged between the second portion 162 and the third portion 163. In other words, guide layer portions in contact with the first and second sides of the p-type electron blocking layer 17 respectively may have different or equal compositions. If the distance from the active layer 10 to the p-type electron blocking layer 17 is excessively increased, however, the function of suppressing an overflow of carriers may be reduced, to result in inferior luminous efficiency.

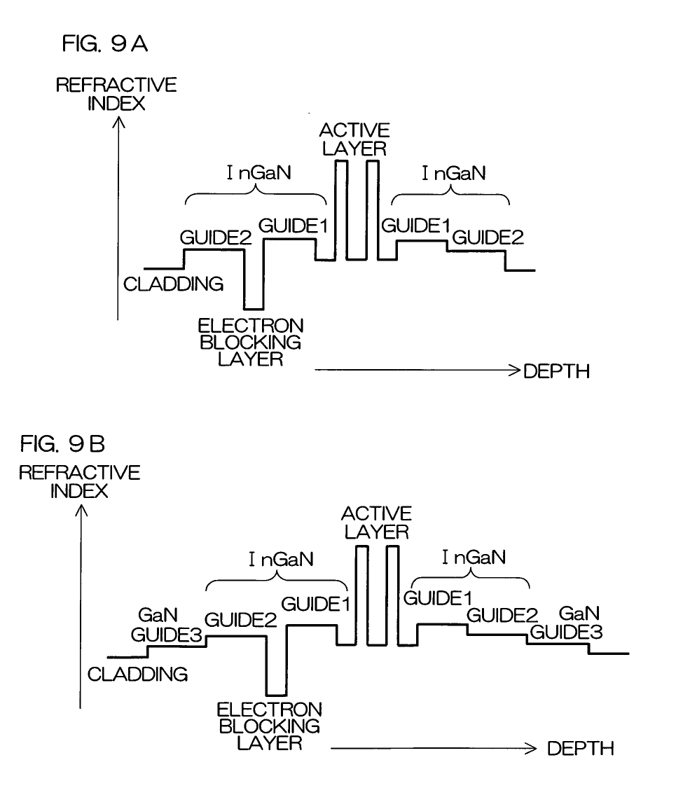

FIG. 9A is a diagram schematically showing the refractive indices of the layers in the structure shown in FIG. 7, and FIG. 9B is a diagram schematically showing the refractive indices of the layers in the structure shown in FIG. 8. Referring to each of FIGS. 9A and 9B, the axis of abscissas shows depths from the surface of the group III nitride semiconductor multilayer structure 2, and the axis of ordinates shows the refractive indices. In each structure, the refractive indices of the guide layers 15 and 16 are increased toward the side of the active layer 10. Thus, the refractive indices can be increased toward the active layer 10, whereby an excellent light confining effect can be attained without increasing the thicknesses of the InGaN layers. Further, the average In composition in the overall guide layers 15 and 16 can be reduced. Thus, concentration of compressive stress can be reduced around the active layer 10, whereby formation of defects can be suppressed. Consequently, the luminous efficiency can be improved.

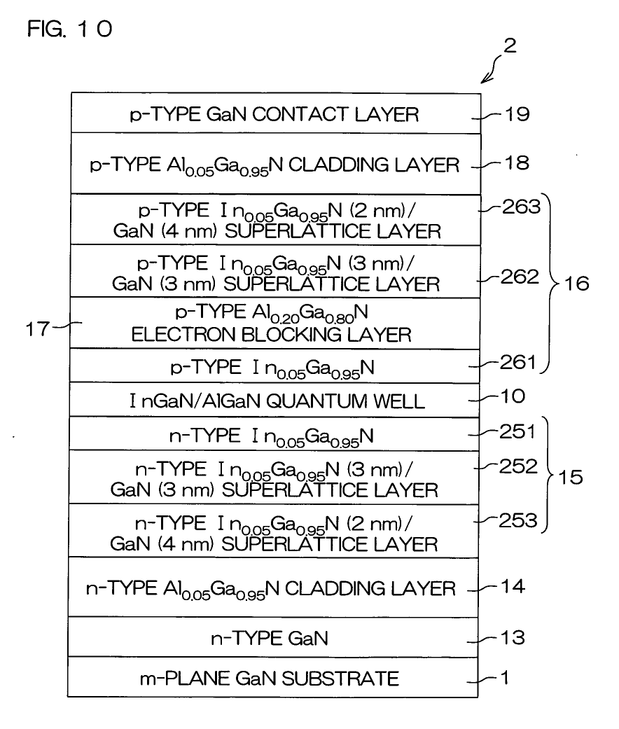

FIG. 10 is a diagram showing further examples of the compositions of the layers constituting the group III nitride semiconductor multilayer structure 2. Referring to FIG. 10, the n-type guide layer 15 is formed by stacking a first portion 251 made of InGaN (In_{0.05}Ga_{0.95}N in the example shown in FIG. 10), a second portion 252 having a superlattice structure and a third portion 253 having a superlattice structure. The average In composition in the second portion 252 is smaller than the In composition in the first portion 251. The average In composition in the third portion 253 is smaller than that in the second portion 252. More specifically, the second portion 252 has a superlattice structure having a cycle of 6 nm formed by alternately repetitively stacking In_{0.05}Ga_{0.95}N layers each having a thickness of 3 nm and GaN layers each having a thickness of 3 nm. The third portion 253 has a superlattice structure having a cycle of 6 nm formed by alternately repetitively stacking In_{0.05}Ga_{0.95}N layers each having a thickness of 2 nm and GaN layers each having a thickness of 4 nm. In other words, the average In compositions are modulated by changing the ratios between the thicknesses of the layers constituting the superlattice structures. The first portion 251 having the largest In composition is disposed on a side closer to the active layer 10 than the second and third portions 252 and 253. The second portion 252 having the second largest In composition (the average In composition) is disposed on a side closer to the active layer 10 than the third portion 253.

Similarly, the p-type guide layer 16 has a first portion 261 made of InGaN (In_{0.05}Ga_{0.95}N in the example shown in FIG. 10), a second portion 262 having a superlattice structure and a third portion 263 having a superlattice structure. The p-type AlGaN electron blocking layer 17 is interposed between the first portion 261 and the second portion 262. The average In composition in the second portion 262 is smaller than the In composition in the first portion 261. The average In composition in the third portion 263 is smaller than that in the second portion 262. More specifically, the second portion 262 has a superlattice structure having a cycle of 6 nm formed by alternately repetitively stacking In_{0.05}Ga_{0.95}N layers each having a thickness of 3 nm and GaN layers each having a thickness of 3 nm. The third portion 263 has a superlattice structure having a cycle of 6 nm formed by alternately repetitively stacking In_{0.05}Ga_{0.95}N layers each having a thickness of 2 nm and GaN layers each having a thickness of 4 nm. In other words, the average In compositions are modulated by changing the ratios between the thicknesses of the layers constituting the superlattice structures. The first portion 261 having the largest In composition is disposed on a side closer to the active layer 10 than the second and third portions 262 and 263. The second portion 262 having the second largest In composition (the average In composition) is disposed on a side closer to the active layer 10 than the third portion 263.

Also according to the structure, the refractive indices of the guide layers 15 and 16 can be increased toward the active layer 10, whereby an excellent light confining effect can be attained while reducing the thicknesses of the guide layers 15 and 16 and the overall average In composition. Thus, excellent luminous efficiency can be implemented while suppressing crystal defects.

The first portion 261 may also have a superlattice structure, to implement a required average In composition by the ratio between the thicknesses of layers constituting the same. Each superlattice structure may not be formed by the InGaN layers and the GaN layers, but first InGaN layers having a relatively high In composition and second InGaN layers having a relatively low In composition may alternatively be alternately repetitively stacked to form the superlattice structure. Further, the p-type electron blocking layer 17 may not be arranged between the first portion 261 and the second portion 262 having different In compositions, but may alternatively be arranged in an intermediate portion of the thickness of the first portion 261, the second portion 262 or the third portion 263. Further alternatively, the p-type electron blocking layer 17 may be arranged between the second portion 262 and the third portion 263. In other words, guide layer portions in contact with the first and second sides of the p-type electron blocking layer 17 respectively may have different or equal compositions. If the distance from the active layer 10 to the p-type electron blocking layer 17 is excessively increased, however, the function of suppressing an overflow of carriers may be reduced, to result in inferior luminous efficiency.

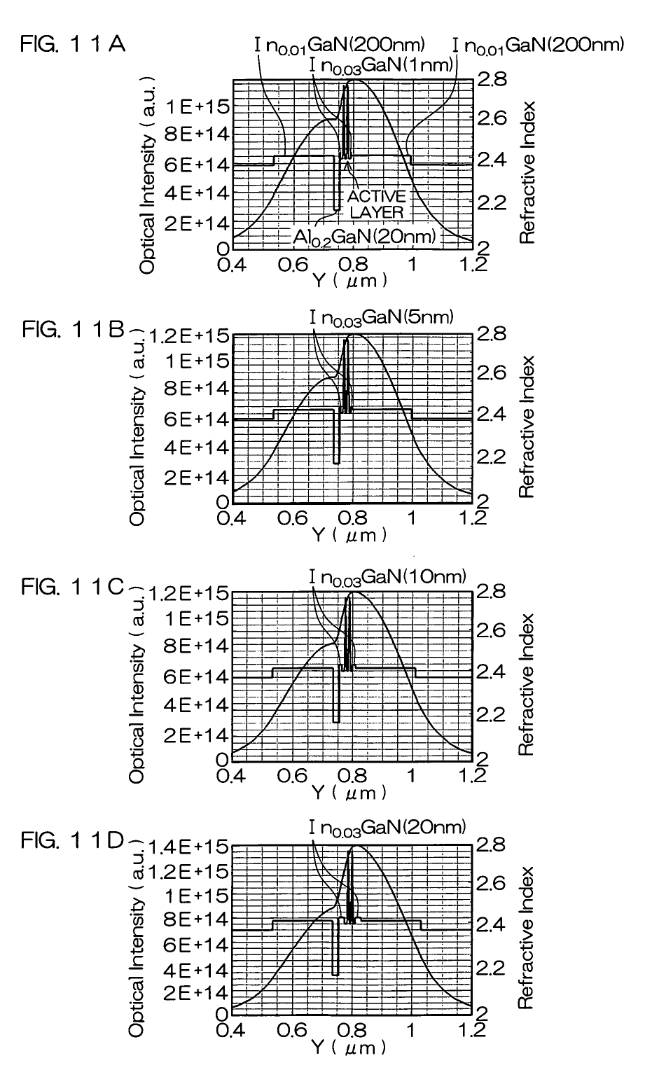

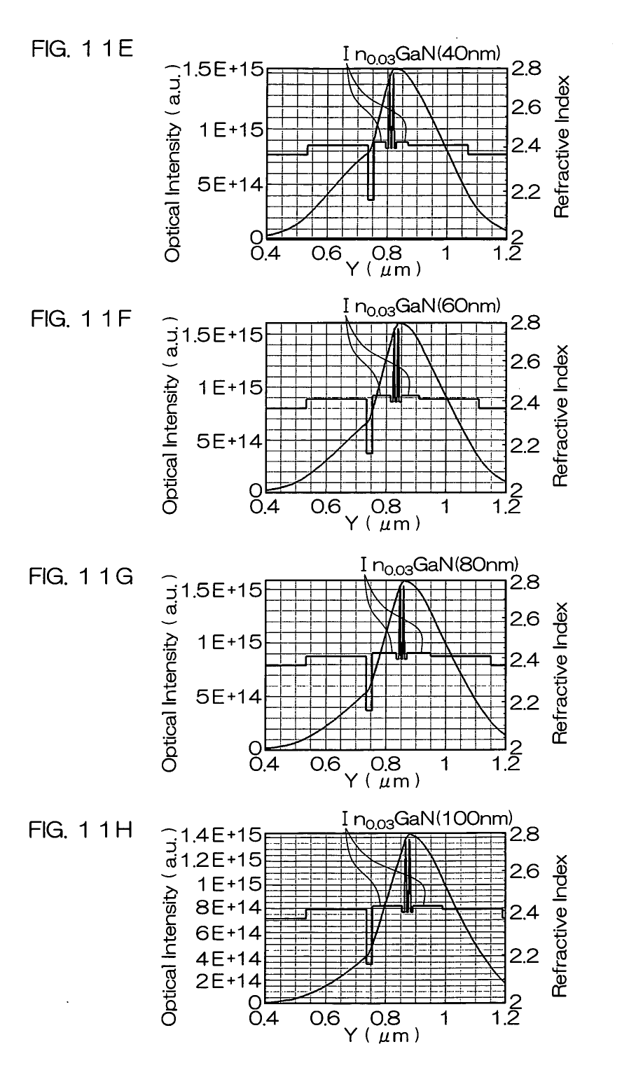

FIGS. 11A to 11H show results of a simulation of optical intensity conducted on the structure shown in FIG. 7. Referring to each of FIGS. 11A to 11H, the axis of abscissas shows depths Y (μm) from the surface of the group III nitride semiconductor multilayer structure 2, the stepwise line shows the refractive indices of the respective layers, and the arched curve shows the optical intensity levels (arbitrary unit). The emission wavelength was set to 500 nm (green), and the p-type electron blocking layer 17 was composed of Al_{0.2}Ga_{0.8}N and had a thickness of 20 nm. In the layers constituting the guide layers 15 and 16, the second portions 152 and 162 farther from the active layer 10 were composed of In_{0.01}Ga_{0.99}N and had thicknesses of 200 nm. In the layers constituting the guide layers 15 and 16, further, the first portions 151 and 161 closer to the active layer 10 were composed of In_{0.03}Ga_{0.97}N, and the thicknesses thereof (i.e., the distance from the active layer 10 to the p-type electron blocking layer 17) were set to various levels in the range of 1 nm to 100 nm, as shown in FIGS. 11A to 11H.

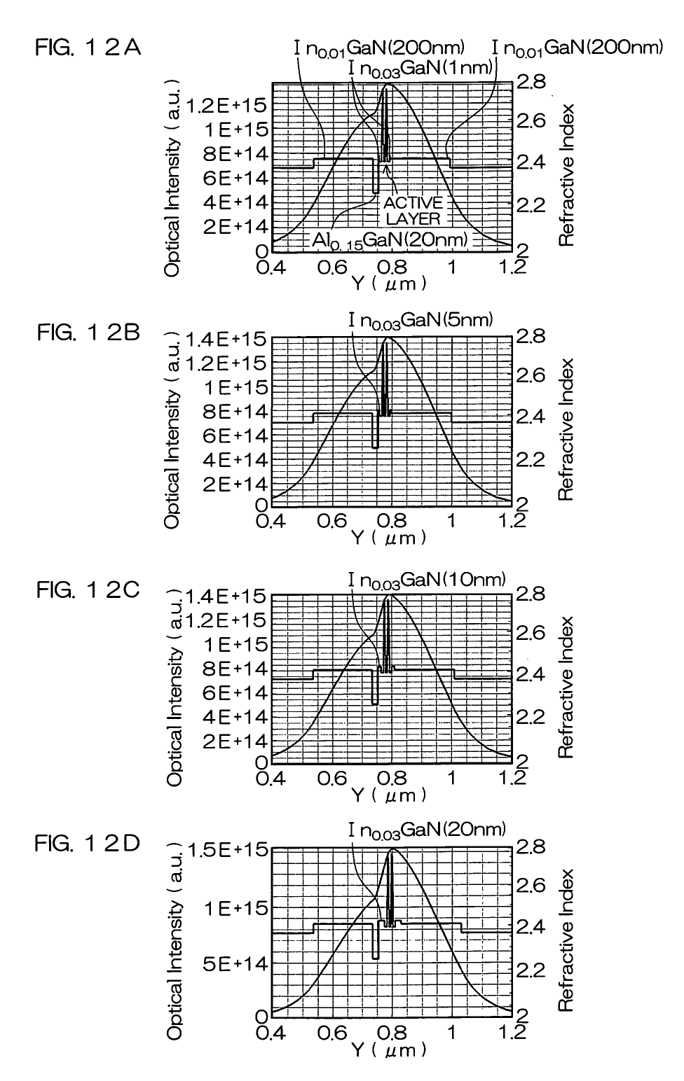

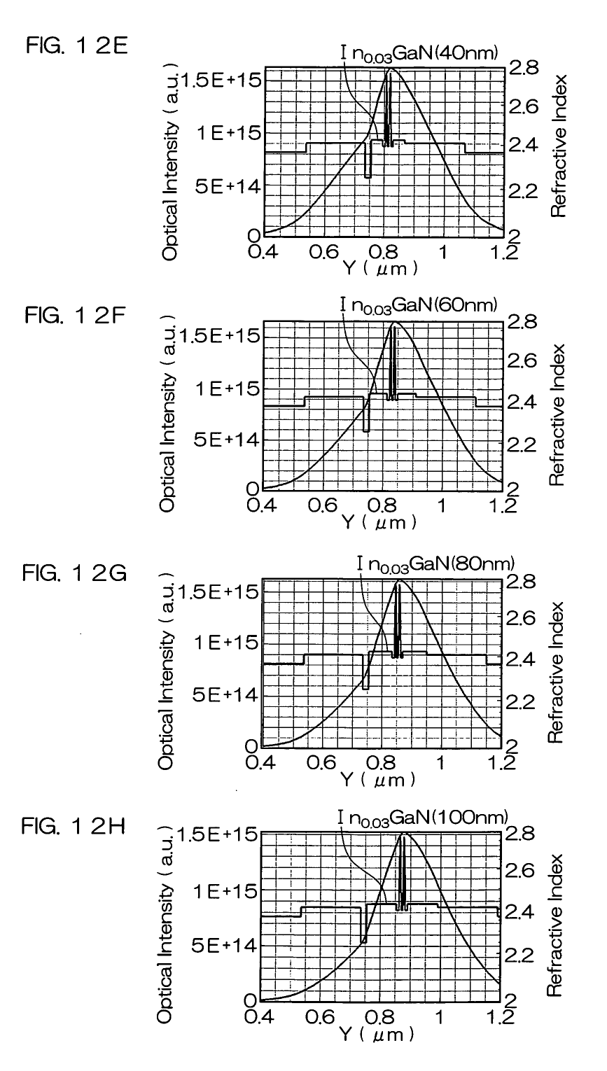

FIGS. 12A to 12H show results of another simulation of optical intensity conducted on the structure shown in FIG. 7. The difference from the simulation shown in FIGS. 11A to 11H resides in that the p-type AlGaN electron blocking layer 17 was composed of Al_{0.15}Ga_{0.85}N.

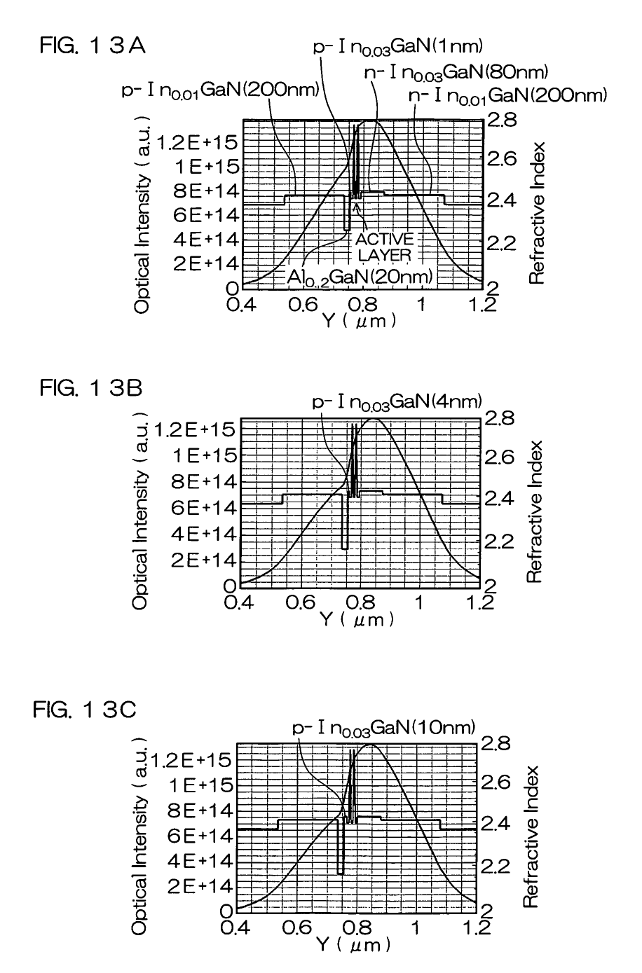

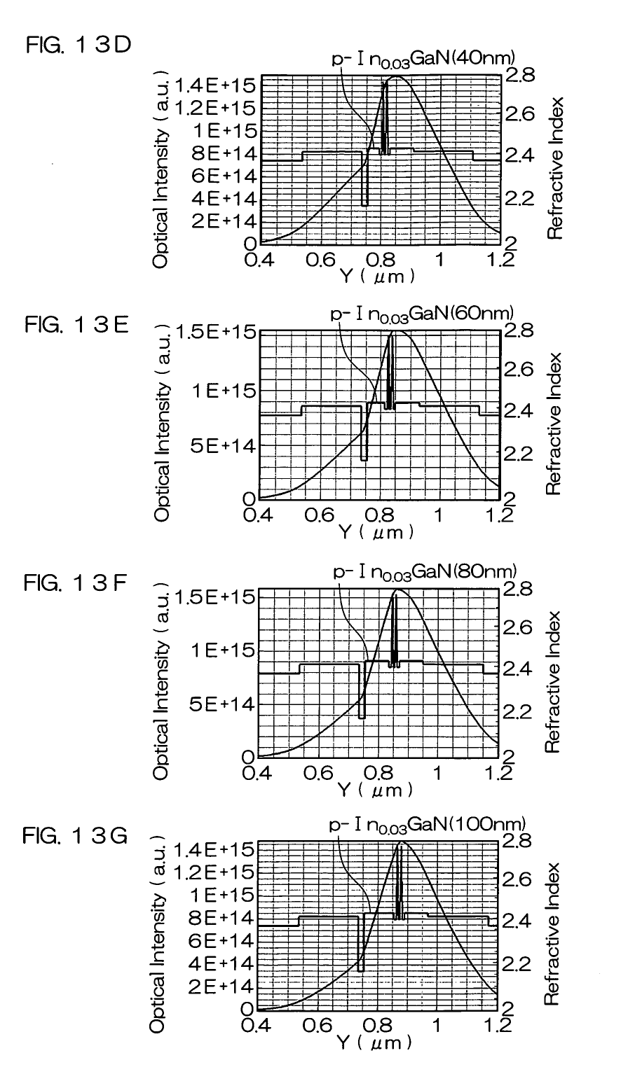

FIGS. 13A to 13G show results of still another simulation of optical intensity conducted on the structure shown in FIG. 7. The difference from the simulation shown in FIGS. 11A to 11H resides in that the thickness of the first portion 151 of the n-type guide layer 15 closer to the active layer 10 was fixed to 80 nm. In other words, the thickness of only the first portion 161 of the p-type guide layer 16 was set to various levels in the range of 1 nm to 100 nm, as shown in FIGS. 13A to 13G.

The simulation results are evaluated as follows:

In each of the simulation results shown in FIGS. 11A to 11D, a clear step is formed in the region of the p-type layers in the profile of the optical intensity. In other words, the optical intensity profile has the so-called two-stage peak shape. Therefore, light confinement is insufficient, and the shape of a far field pattern may be deteriorated. In each of the simulation results shown in FIGS. 11E to 11H, on the other hand, the inflection point in the region of the p-type layers is positioned in the range of not more than about half the maximum intensity, to provide an optical intensity profile close to Gaussian distribution. Therefore, excellent light confinement can be attained, and the far field pattern is conceivably also excellent. When the thicknesses of the first portions 151 and 161 of the guide layers 15 and 16 closer to the active layer 10 are not less than 40 nm, therefore, a semiconductor laser device having excellent luminous intensity can conceivably be implemented. From the simulation result shown in FIG. 11H, however, it is apprehended that the optical intensity is rendered insufficient if the thicknesses of the first portions 151 and 161 exceed 100 nm. Therefore, the thicknesses of the first portions 151 and 161 are conceivably preferably not more than 100 nm.

The simulation results shown in FIGS. 12A to 12H allow consideration similar to that on the simulation results shown in FIGS. 11A to 11H. Therefore, it is understood that the composition of the p-type AlGaN electron blocking layer 17 does not exert a remarkable influence on the light confinement characteristics. In general, the Al composition in the p-type electron blocking layer 17 is set in the range of 15% to 20%. This is because no electron blocking effect can be expected if the Al composition is less than 15% while it may be so difficult to form the electron blocking layer 17 as a p-type layer that the same cannot supply the holes to the active layer 10 if the Al composition therein exceeds 20%.

In each of the simulation results shown in FIGS. 13A to 13C, a clear step is formed in the region of the p-type layers in the profile of the optical intensity. In other words, the optical intensity profile has the so-called two-stage peak shape. In each of the simulation results shown in FIGS. 13D to 13G, on the other hand, the inflection point in the region of the p-type layers is positioned in the range of not more than about half the maximum intensity, to provide an optical intensity profile close to Gaussian distribution. When the thickness of the first portion 161 of the p-type guide layer 16 closer to the active layer 10 is not less than 40 nm, therefore, a semiconductor laser device having excellent luminous efficiency can conceivably be implemented. From the simulation result shown in FIG. 13G, however, it is apprehended that the optical intensity is rendered insufficient if the thickness of the first portion 161 exceeds 100 nm. Therefore, the thickness of the first portion 161 is conceivably preferably not more than 100 nm.

It is understood from the above that an excellent optical intensity profile can be obtained by setting the distance from the active layer 10 to the p-type AlGaN electron blocking layer 17 to not less than 40 nm. It is also understood that sufficient optical intensity can be obtained by setting the distance to not more than 100 nm.

Comparing the simulation results shown in FIGS. 11A to 11H with those shown in FIGS. 13A to 13G, however, the center of the optical intensity profile shifts toward the side closer to the n-type semiconductor layered portion 11 than the active layer 10 in each of the simulation results shown in FIGS. 13A to 13G. Therefore, it is understood that the n-type guide layer 15 and the p-type guide layer 16 are preferably rendered symmetrical with respect to the active layer 10, in order to improve the luminous efficiency.

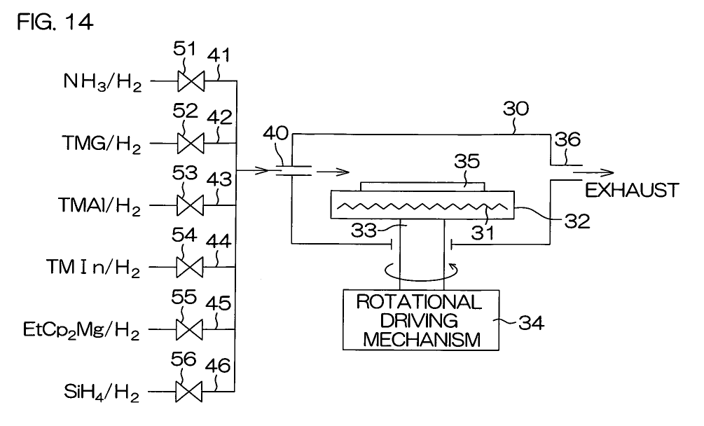

FIG. 14 is a schematic diagram for illustrating the structure of a processing apparatus for growing the layers constituting the group III nitride semiconductor multilayer structure 2. A susceptor 32 having a built-in heater 31 is arranged in a processing chamber 30. The susceptor 32 is coupled to a rotating shaft 33, which in turn is rotated by a rotational driving mechanism 34 arranged outside the processing chamber 30. Thus, the susceptor 32 holds a wafer 35 to be treated, so that the wafer 35 can be heated to a prescribed temperature and rotated in the processing chamber 30. The wafer 35 is a GaN single-crystalline wafer constituting the aforementioned GaN single-crystalline substrate 1.

An exhaust pipe 36 is connected to the processing chamber 30. The exhaust pipe 36 is connected to exhaust equipment such as a rotary pump. Thus, the pressure in the processing chamber 30 is set to 1/10 atm to ordinary pressure, and the atmosphere in the processing chamber 30 is regularly exhausted.

On the other hand, a source gas feed passage 40 for feeding source gas toward the surface of the wafer 35 held by the susceptor 32 is introduced into the processing chamber 30. A nitrogen material pipe 41 feeding ammonia as nitrogen source gas, a gallium material pipe 42 feeding trimethyl gallium (TMG) as gallium source gas, an aluminum material pipe 43 feeding trimethyl aluminum (TMAl) as aluminum source gas, an indium material pipe 44 feeding trimethyl indium (TMIn) as indium source gas, a magnesium material pipe 45 feeding ethylcyclopentadienyl magnesium (EtCp₂Mg) as magnesium source gas and a silicon material pipe 46 feeding silane (SiH₄) as silicon source gas are connected to the source gas feed passage 40. Valves 51 to 56 are interposed in the pipes 41 to 46 respectively. Each source gas is fed along with carrier gas such as hydrogen and/or nitrogen.

For example, a GaN single-crystalline wafer having a major surface defined by an m-plane is held by the susceptor 32 as the wafer 35. In this state, the nitrogen material valve 51 is opened while the valves 52 to 56 are kept closed, so that the carrier gas and ammonia gas (nitrogen source gas) are fed into the processing chamber 30. Further, the heater 31 is electrified, to increase the wafer temperature to 1000° C. to 1100° C. (1050° C., for example). Thus, GaN semiconductors can be grown without roughening the surface.

After the wafer temperature reaches 1000° C. to 1100° C., the nitrogen material valve 51, the gallium material valve 52 and the silicon material valve 56 are opened. Thus, ammonia, trimethyl gallium and silane are fed from the source gas feed passage 40 along with the carrier gas. Consequently, the n-type GaN contact layer 13 consisting of a GaN layer doped with silicon is grown on the surface of the wafer 35.

Then, the aluminum material valve 53 is opened, in addition to the nitrogen material valve 51, the gallium material valve 52 and the silicon material valve 56. Thus, ammonia, trimethyl gallium, silane and trimethyl aluminum are fed from the source gas feed passage 40 along with the carrier gas. Consequently, the n-type AlGaN cladding layer 14 is epitaxially grown on the n-type GaN contact layer 13. The flow rate of each source gas (particularly the aluminum material gas) is adjusted so that the Al composition in the AlGaN cladding layer 14 is not more than 5%.

Then, the aluminum material valve 53 is closed, while the nitrogen material valve 51, the gallium material valve 52, the indium material valve 54 and the silicon material valve 56 are opened. Thus, ammonia, trimethyl gallium, trimethyl indium and silane are fed from the source gas feed passage 40 along with the carrier gas. Consequently, the n-type guide layer 15 is epitaxially grown on the n-type AlGaN cladding layer 14. In the formation of the n-type guide layer 15, the temperature of the wafer 35 is preferably set to 800° C. to 900° C. (850° C., for example).

In order to provide the n-type guide layer 15 in the structure shown in FIG. 7, the second portion 152 having the relatively small In composition is formed first and the first portion 151 having the relatively large In composition is thereafter formed, by adjusting the flow rate of each source gas. In order to provide the n-type guide layer 15 in the structure shown in FIG. 8, on the other hand, the third portion 153 made of GaN (containing no In) is formed first, the second portion 152 made of InGaN having the large In composition is thereafter formed and the first portion 151 having the In composition larger than that in the second portion 152 is formed thereon, by adjusting the flow rate of each source gas. In order to provide the n-type guide layer 15 in the structure shown in FIG. 10, further, the third portion 253 is formed first, the second portion 252 is formed thereon and the first portion 251 is formed thereon, by adjusting the flow rate of each source gas. In order to form each of the second and third portions 252 and 253 having the superlattice structures, a step of forming an n-type InGaN layer having a required thickness and a step of forming an n-type GaN layer having a required thickness are alternately repetitively carried out. In the step of forming the n-type InGaN layer, the nitrogen material valve 51, the gallium material valve 52, the indium material valve 54 and the silicon material valve 56 are opened and the remaining valves 53 and 55 are closed, for feeding ammonia, trimethyl gallium, trimethyl indium and silane to the wafer 35. In the step of forming the n-type GaN layer, the nitrogen material valve 51, the gallium material valve 52 and the silicon material valve 56 are opened and the remaining valves 53, 54 and 55 are closed, for feeding ammonia, trimethyl gallium and silane to the wafer 35.

Then, the silicon material valve 56 is closed, and the active layer 10 (the light emitting layer) having the multiple-quantum well structure is grown. The active layer 10 can be grown by alternately carrying put a step of growing the quantum well layer 221 consisting of an InGaN layer by opening the nitrogen material valve 51, the gallium material valve 52 and the indium material valve 54 for feeding ammonia, trimethyl gallium and trimethyl indium to the wafer 35 and a step of growing the barrier layer 222 consisting of an AlGaN layer by closing the indium material valve 54 and opening the nitrogen material valve 51, the gallium material valve 52 and the aluminum material valve 53 for feeding ammonia, trimethyl gallium and trimethyl aluminum to the wafer 35. More specifically, the barrier layer 222 is formed first, and the quantum well layer 221 is formed thereon. These steps are repeated twice, for example, and the barrier layer 222 is finally formed. In the formation of each barrier layer 222, the flow rate of each source gas (particularly the aluminum material gas) is adjusted so that the Al composition in the formed layer is not more than 5%. In the formation of the active layer 10, the temperature of the wafer 35 is preferably set to 700° C. to 800° C. (730° C., for example), for example.

Then, the aluminum material valve 53 is closed, and the nitrogen material valve 51, the gallium material valve 52, the indium material valve 54 and the magnesium material valve 55 are opened. Thus, ammonia, trimethyl gallium, trimethyl indium and ethylcyclopentadienyl magnesium are fed to the wafer 35, to form the inner portion (the first portion 161 or 261 in the structure shown in FIG. 7, 8 or 10) of the guide layer 16 consisting of a p-type InGaN layer doped with magnesium. The In composition is controlled to a required value by adjusting the flow rate of each source gas. In the formation of the p-type guide layer 16, the temperature of the wafer 35 is preferably set to 800° C. to 900° C. (850° C., for example).

Then, the p-type AlGaN electron blocking layer 17 is formed. In other words, the nitrogen material valve 51, the gallium material valve 52, the aluminum material valve 53 and the magnesium material valve 55 are opened, and the remaining valves 54 and 56 are closed. Thus, ammonia, trimethyl gallium, trimethyl aluminum and ethylcyclopentadienyl magnesium are fed to the wafer 35, to form the p-type AlGaN electron blocking layer 17 consisting of an AlGaN layer doped with magnesium. In the formation of the p-type AlGaN electron blocking layer 17, the temperature of the wafer 35 is preferably set to 900° C. to 1100° C. (1000° C., for example).

Then, the outer portion (the second portion 162 or 262 and the third portion 163 or 263 in the structure shown in FIG. 7, 8 or 10) of the p-type guide layer 16 is formed. In order to provide the p-type guide layer 16 in the structure shown in FIG. 7, the second portion 162 made of InGaN having the In composition smaller than that in the first portion 161 is formed on the p-type AlGaN electron blocking layer 17, by adjusting the flow rate of each source gas. In order to provide the p-type guide layer 16 in the structure shown in FIG. 8, on the other hand, the second portion 162 made of InGaN having the In composition smaller than that in the first portion 161 is first formed on the p-type AlGaN electron blocking layer 17 and the third portion 163 made of GaN (containing no In) is thereafter formed thereon, by adjusting the flow rate of each source gas. In order to provide the p-type guide layer 16 in the structure shown in FIG. 10, further, the second portion 252 is first formed on the p-type AlGaN electron blocking layer 17 and the third portion 263 is formed thereon, by adjusting the flow rate of each source gas. In order to form each of the second and third portions 262 and 263 having the superlattice structures, a step of forming a p-type InGaN layer having a required thickness and a step of forming a p-type GaN layer having a required thickness are alternately repetitively carried out. In the step of forming the p-type InGaN layer, the nitrogen material valve 51, the gallium material valve 52, the indium material valve 54 and the magnesium material valve 55 are opened and the remaining valves 53 and 56 closed, for feeding ammonia, trimethyl gallium, trimethyl indium and ethylcyclopentadienyl magnesium to the wafer 35. In the step of forming the p-type GaN layer, the nitrogen material valve 51, the gallium material valve 52 and the magnesium material valve 55 are opened and the remaining valves 53, 54 and 56 are closed, for feeding ammonia, trimethyl gallium and ethylcyclopentadienyl magnesium to the wafer 35.

Then, the p-type AlGaN cladding layer 18 is formed. In other words, the nitrogen material valve 51, the gallium material valve 52, the aluminum material valve 53 and the magnesium material valve 55 are opened, and the remaining valves and 56 are closed. Thus, ammonia, trimethyl gallium, trimethyl aluminum and ethylcyclopentadienyl magnesium are fed to the wafer 35, to form the cladding layer 18 consisting of a p-type AlGaN layer doped with magnesium. In the formation of the p-type AlGaN cladding layer 18, the temperature of the wafer 35 is preferably set to 900° C. to 1100° C. (1000° C., for example). Further, the flow rate of each source gas (particularly the aluminum source gas) is preferably adjusted so that the Al composition in the p-type AlGaN cladding layer 18 is not more than 5%.

Then, the p-type GaN contact layer 19 is formed. In other words, the nitrogen material valve 51, the gallium material valve 52 and the magnesium material valve 55 are opened, and the remaining valves 53, 54 and 56 are closed. Thus, ammonia, trimethyl gallium and ethylcyclopentadienyl magnesium are fed to the wafer 35, to form the p-type GaN contact layer 19 consisting of a GaN layer doped with magnesium. In the formation of the p-type GaN contact layer 19, the temperature of the wafer 35 is preferably set to 900° C. to 1100° C. (1000° C., for example).

The layers constituting the p-type semiconductor layered portion 12 are preferably crystal-grown at an average growth temperature of not more than 1000° C. Thus, thermal damage on the active layer 10 can be reduced.

When each of the layers 10 and 13 to 19 constituting the group III nitride semiconductor multilayer structure 2 is grown on the wafer 35 (the GaN single-crystalline substrate 1), a V/III ratio indicating the ratio of the molar fraction of the nitrogen material (ammonia) to the molar fraction of the gallium material (trimethyl gallium) fed to the wafer 35 in the treating chamber 30 is maintained at a high value of not less than 1000 (preferably not less than 3000). More specifically, the average V/III ratio is preferably not less than 1000 in any part from the n-type cladding layer 14 to the uppermost p-type GaN contact layer 19. Thus, excellent crystals having small numbers of point defects can be obtained in all of the n-type cladding layer 14, the active layer 10 and the p-type cladding layer 18.

According to the embodiment, the group III nitride semiconductor multilayer structure 2 having the major surface defined by the m-plane or the like is grown in a dislocation-free state in a planar manner at the aforementioned high V/III ratio without interposing a buffer layer between the GaN single-crystalline substrate 1 and the group III nitride semiconductor multilayer structure 2. The group III nitride semiconductor multilayer structure 2 has neither stacking faults nor threading dislocations formed from the major surface of the GaN single-crystalline substrate 1.

When the group III nitride semiconductor multilayer structure 2 is grown on the wafer 35 in the aforementioned manner, the wafer 35 is introduced into an etching apparatus, and the ridge stripe 20 is formed by partially removing the p-type semiconductor layered portion 12 by dry etching such as plasma etching, for example. The ridge stripe 20 is formed to be parallel to the c-axis direction.

After the formation of the ridge stripe 20, the insulating layers 6 are formed. The insulating layers 6 are formed by a lift-off step, for example. In other words, the insulating layers 6 can be formed by forming a striped mask, thereafter forming a thin insulator film to entirely cover the p-type AlGaN cladding layer 18 and the p-type GaN contact layer 19, and thereafter lifting off the thin insulator film to expose the p-type GaN contact layer 19.

Then, the p-type electrode 4 in ohmic contact with the p-type GaN contact layer 19 is formed, and the n-type electrode 3 in ohmic contact with the n-type GaN contact layer 13 is formed. The electrodes 3 and 4 can be formed in a metal vapor deposition apparatus employing resistance heating or an electron beam, for example.

The next step is division into each individual device. In other words, each device constituting the semiconductor laser diode is cut out by cleaving the wafer 35 in a direction parallel to the ridge stripe 20 and a direction perpendicular thereto. The wafer 35 is cleaved in the direction parallel to the ridge stripe 20 along the a-plane. Further, the wafer 35 is cleaved in the direction perpendicular to the ridge stripe 20 along the c-plane. Thus, the cavity end face 21 defined by the +c-plane and the cavity end face 22 defined by the −c-plane are formed.

Then, the aforementioned insulating films 23 and 24 are formed on the cavity end faces 21 and 22 respectively. The insulating films 23 and 24 can be formed by electron cyclotron resonance (ECR) film formation, for example.

While the embodiment of the present invention has been described, the present invention may be embodied in other ways.

For example, while the guide layers 15 and 16 have two- or three-layer structures in the aforementioned embodiment, each of the guide layers 15 and 16 may alternatively be constituted of not less than four layers. In this case, the In composition xᵢ in each layer may be so set that xᵢ₋₁>xᵢ>xᵢ₊₁ holds with respect to arbitrary i assuming that the composition of an i-th layer from the side closer to the active layer 10 is expressed as InₓᵢGa₁₋ₓᵢN (0≦xᵢ≦1 and i=1, 2, 3, . . . ).

While the ridge stripe 20 is formed parallelly to the c-axis in the aforementioned embodiment, the ridge stripe 20 may alternatively be formed parallelly to the a-axis, and the cavity end faces may be defined by a-planes. The major surface of the substrate 1 is not restricted to the m-plane, but may alternatively be defined by an a-plane which is another nonpolar plane, or by a semipolar plane.

The thicknesses of and the impurity concentrations in the layers constituting the group III nitride semiconductor multilayer structure 2 are merely examples, and appropriate values can be properly selected and employed.

After the formation of the group III nitride semiconductor multilayer structure 2, the substrate 1 may be removed by laser lift off or the like, so that the semiconductor laser diode may have no substrate 1.

While the device has the active layer of the multiple-quantum well structure provided with the plurality of quantum well layers in the aforementioned embodiment, the active layer may alternatively have a quantum well structure provided with one quantum well layer.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

The present application corresponds to Japanese Patent Application No. 2009-21952 filed in the Japan Patent Office on Feb. 2, 2009, and the entire disclosure of the application is incorporated herein by reference.

What is claimed is:

1. A semiconductor laser device having a semiconductor laser diode structure made of group III nitride semiconductors having major growth surfaces defined by nonpolar planes or semipolar planes, wherein
the semiconductor laser diode structure comprises:
a p-type cladding layer and an n-type cladding layer;
a p-type guide layer and an n-type guide layer held between the p-type cladding layer and the n-type cladding layer; and
an active layer containing In held between the p-type guide layer and the n-type guide layer, and
In compositions in the p-type guide layer and the n-type guide layer are increased as approaching the active layer respectively.

2. The semiconductor laser device according to claim 1, wherein
each of the p-type guide layer and the n-type guide layer has a plurality of InₓGa₁₋ₓN layers (0≦x≦1), and the plurality of InₓGa₁₋ₓN layers are stacked in such order that the In compositions therein are increased as approaching the active layer.

3. The semiconductor laser device according to claim 2, wherein
at least one of the plurality of InₓGa₁₋ₓN layers is constituted of an InGaN superlattice, and an average In composition is modulated by adjusting a ratio between thicknesses of layers constituting the InGaN superlattice.

4. The semiconductor laser device according to claim 1, wherein
a p-type AlGaN electron blocking layer is interposed in an intermediate portion of a total thickness of the p-type guide layer.

5. The semiconductor laser device according to claim 4, wherein
a distance from the active layer to the p-type AlGaN electron blocking layer is not less than 40 nm.

6. The semiconductor laser device according to claim 4, wherein
a distance from the active layer to the p-type AlGaN electron blocking layer is not less than 40 nm and not more than 100 nm.

7. The semiconductor laser device according to claim 2, wherein
a p-type AlGaN electron blocking layer is interposed in an intermediate portion of a total thickness of the p-type guide layer.

8. The semiconductor laser device according to claim 7, wherein
a distance from the active layer to the p-type AlGaN electron blocking layer is not less than 40 nm.

9. The semiconductor laser device according to claim 7, wherein
a distance from the active layer to the p-type AlGaN electron blocking layer is not less than 40 nm and not more than 100 nm.

10. The semiconductor laser device according to claim 3, wherein
a p-type AlGaN electron blocking layer is interposed in an intermediate portion of a total thickness of the p-type guide layer.

11. The semiconductor laser device according to claim 10, wherein
a distance from the active layer to the p-type AlGaN electron blocking layer is not less than 40 nm.

12. The semiconductor laser device according to claim 10, wherein
a distance from the active layer to the p-type AlGaN electron blocking layer is not less than 40 nm and not more than 100 nm.
